(19) United States
(12) Patent Application Publication
(10) Pub. No.: US 2016/0056329 A1
(43) Pub. Date: Feb. 25, 2016

(54) SEMICONDUCTOR LIGHT EMITTING ELEMENT AND METHOD FOR MANUFACTURING THE SAME

(71) Applicant: Kabushiki Kaisha Toshiba, Minato-ku (JP)

(72) Inventors: Hisashi YOSHIDA, Koto (JP); Toshiki Hikosaka, Kawasaki (JP); Shigeya Kimura, Yokohama (JP); Hajime Nago, Yokohama (JP); Shinya Nunoue, Ichikawa (JP)

(73) Assignee: Kabushiki Kaisha Toshiba, Minato-ku (JP)

(21) Appl. No.: 14/714,500

(22) Filed: May 18, 2015

(30) Foreign Application Priority Data
Aug. 25, 2014 (JP) 2014-170147
Apr. 2, 2015 (JP) 2015-075647

(51) Int. Cl. H01L 33/06; H01L 33/32; H01L 33/24; H01L 33/00

(52) U.S. Cl. CPC H01L 33/06; H01L 33/0025; H01L 33/0075; H01L 33/32; H01L 33/24

(57) ABSTRACT

According to one embodiment, a semiconductor light emitting element includes a first semiconductor layer of a first conductivity type, a second semiconductor layer of a second conductivity type separated from the first semiconductor layer in a first direction, a light emitting layer provided between the first and second semiconductor layers, and a first intermediate unit provided between the first semiconductor layer and the light emitting layer. The light emitting layer includes a well layer including a nitride semiconductor including In. The first intermediate unit includes stacked bodies. The stacked bodies are arranged in the first direction. Each of the stacked bodies includes a first layer of Inₓ₁Ga₁₋ₓ₁N, a second layer of Al_{y1}Ga_{1-y1}N provided between the first layer and the light emitting layer to contact the first layer, and a third layer of Al_{y2}Ga_{1-y2}N provided between the second layer and the light emitting layer to contact the second layer.

### CROSS-REFERENCE TO RELATED APPLICATIONS

This application is based upon and claims the benefit of priority from Japanese Patent Application No. 2014-170147, filed on Aug. 25, 2014; and Japanese Patent Application No. 2015-075647, filed on Apr. 2, 2015; the entire contents of which are incorporated herein by reference.

### FIELD

Embodiments described herein relate generally to a semiconductor light emitting element and a method for manufacturing the same.

### BACKGROUND

It is desirable to the increase of the efficiency of semiconductor light emitting elements (e.g., light emitting diodes) that use, for example, nitride semiconductors.

### BRIEF DESCRIPTION OF THE DRAWINGS

FIG. 1 is a schematic cross-sectional view showing a semiconductor light emitting element according to a first embodiment;

FIG. 2 is a schematic cross-sectional view showing a portion of the semiconductor light emitting element according to the first embodiment;

FIG. 3 is a schematic cross-sectional view showing a portion of the semiconductor light emitting element according to the first embodiment;

FIG. 4A to FIG. 4C are atomic force microscope images showing the semiconductor light emitting element of a first reference example;

FIG. 5A to FIG. 5F are micrographs showing the semiconductor light emitting element of the first reference example;

FIG. 6A to FIG. 6D are schematic views showing characteristics of the semiconductor light emitting elements;

FIG. 7A to FIG. 7D are schematic views showing characteristics of the semiconductor light emitting elements;

FIG. 8A to FIG. 8E are graphs of characteristics of the semiconductor light emitting element;

FIG. 9 is a schematic cross-sectional view showing a semiconductor light emitting element according to a second embodiment; and

FIG. 10 is a flowchart showing the method for manufacturing the semiconductor light emitting element according to the third embodiment.

### DETAILED DESCRIPTION

According to one embodiment, a semiconductor light emitting element includes a first semiconductor layer of a first conductivity type, a second semiconductor layer of a second conductivity type separated from the first semiconductor layer in a first direction, a light emitting layer provided between the first semiconductor layer and the second semiconductor layer, and a first intermediate unit provided between the first semiconductor layer and the light emitting layer. The light emitting layer includes a well layer. The well layer includes a nitride semiconductor including In. The first intermediate unit includes a plurality of stacked bodies. The stacked bodies are arranged in the first direction. Each of the stacked bodies includes a first layer of Inₓ₁Ga₁₋ₓ₁N (0<x1<1), a second layer of Al_{y1}Ga_{1-y1}N (0<y1<1) provided between the first layer and the light emitting layer to contact the first layer, and a third layer of Al_{y2}Ga_{1-y2}N (0≦y2<y1) provided between the second layer and the light emitting layer to contact the second layer. A screw dislocation density of the first semiconductor layer is 1×10⁸/cm² or more.

According to one embodiment, a semiconductor light emitting element includes a first semiconductor layer of a first conductivity type formed on a silicon substrate, a first intermediate unit provided on the first semiconductor layer, a light emitting layer provided on the first intermediate unit, and a second semiconductor layer of a second conductivity type provided on the light emitting layer. The light emitting layer includes a well layer including a nitride semiconductor including In. The first intermediate unit includes a plurality of stacked bodies. The stacked bodies are arranged in a first direction from the first semiconductor layer toward the second semiconductor layer. Each of the stacked bodies includes a first layer of Inₓ₁Ga₁₋ₓ₁N (0<x1<1), a second layer of Al_{y1}Ga_{1-y1}N (0<y1<1) provided between the first layer and the light emitting layer to contact the first layer, and a third layer of Al_{y2}Ga_{1-y2}N (0≦y2<y1) provided between the second layer and the light emitting layer to contact the second layer.

According to one embodiment, a method for manufacturing a semiconductor light emitting element is disclosed. The method can include forming a first semiconductor layer on a silicon substrate, forming a first intermediate unit on the first semiconductor layer, and forming a light emitting layer on the first intermediate unit. In addition, the method can include forming a second semiconductor layer of a second conductivity type on the light emitting layer. The light emitting layer includes a well layer including a nitride semiconductor including In. The forming of the first intermediate unit includes forming a plurality of stacked bodies. The stacked bodies are arranged in a direction intersecting the silicon substrate. Each of the stacked bodies includes a first layer of Inₓ₁Ga₁₋ₓ₁N (0<x1<1), a second layer of Al_{y1}Ga_{1-y1}N (0<y1≦1) provided on the first layer to contact the first layer, and a third layer of Al_{y2}Ga_{1-y2}N (0≦y2<y1) provided on the second layer to contact the second layer.

Various embodiments will now be described hereinafter with reference to the accompanying drawings.

The drawings are schematic or conceptual; and the relationships between the thicknesses and widths of portions, the proportions of sizes between portions, etc., are not necessarily the same as the actual values thereof. Further, the dimensions and/or the proportions may be illustrated differently between the drawings, even in the case where the same portion is illustrated.

In the drawings and the specification of the application, components similar to those described in regard to a drawing thereinabove are marked with like reference numerals, and a detailed description is omitted as appropriate.

### First Embodiment

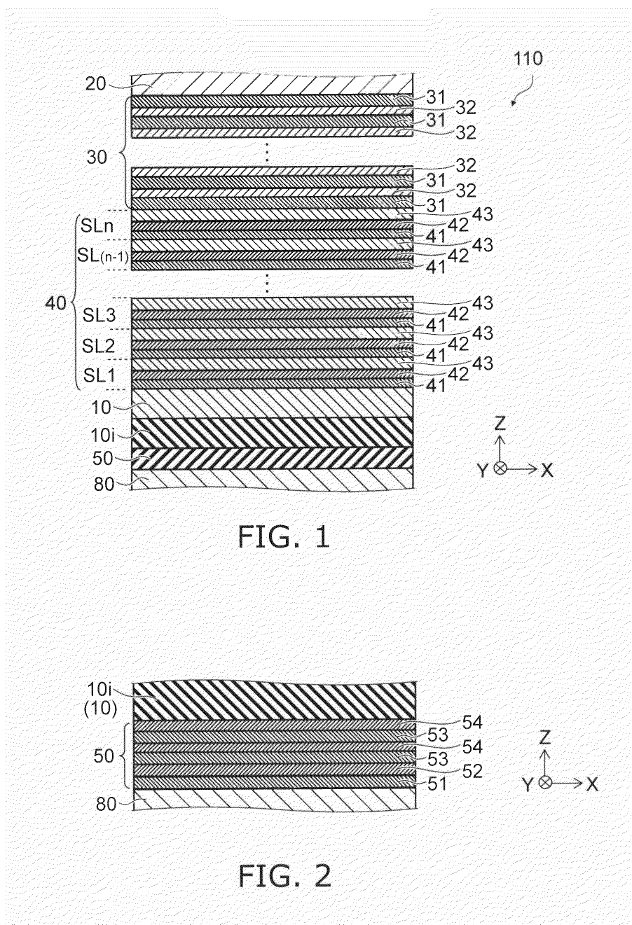

FIG. 1 is a schematic cross-sectional view illustrating a semiconductor light emitting element according to a first embodiment.

As shown in FIG. 1, the semiconductor light emitting element 110 according to the embodiment includes a first semiconductor layer 10, a second semiconductor layer 20, a light emitting layer 30, and a first intermediate unit 40.

The first semiconductor layer 10 has a first conductivity type. The second semiconductor layer 20 has a second conductivity type. For example, the first conductivity type is an n-type; and the second conductivity type is a p-type. The first conductivity type may be the p-type; and the second conductivity type may be the n-type. Hereinbelow, the first conductivity type is taken to be the n-type; and the second conductivity type is taken to be the p-type.

The second semiconductor layer 20 is separated from the first semiconductor layer 10 in a first direction.

The first direction is taken as a Z-axis direction. One direction perpendicular to the Z-axis direction is taken as an X-axis direction. A direction perpendicular to the Z-axis direction and the X-axis direction is taken as a Y-axis direction.

The first semiconductor layer 10 and the second semiconductor layer 20 include, for example, nitride semiconductors.

The first semiconductor layer 10 includes, for example, a GaN layer including an n-type impurity. The n-type impurity includes at least one of Si, Ge, Te, or Sn. The first semiconductor layer 10 includes, for example, an n-side contact layer.

The second semiconductor layer 20 includes, for example, a GaN layer including a p-type impurity. The p-type impurity includes at least one of Mg, Zn, or C. The second semiconductor layer 20 includes, for example, a p-side contact layer.

The light emitting layer 30 is provided between the first semiconductor layer 10 and the second semiconductor layer 20. The light emitting layer 30 includes a well layer 32. The well layer 32 includes a nitride semiconductor including In. The well layer 32 includes, for example, In_{w1}Ga_{1-w1}N (0<w1<1).

A current is supplied to the light emitting layer 30 via the first semiconductor layer 10 and the second semiconductor layer 20. Light is emitted from the light emitting layer 30. The peak wavelength of the light (the emitted light) emitted from the light emitting layer 30 is, for example, not less than 435 nanometers (nm) and not more than 460 nm. The emitted light is, for example, blue. The intensity of the emitted light is a maximum at the peak wavelength. In the embodiment, the peak wavelength is arbitrary.

The first intermediate unit 40 is provided between the first semiconductor layer 10 and the light emitting layer 30. The first intermediate unit 40 includes multiple stacked bodies SL (stacked bodies SL1 to SLn). The number n of stacked bodies SL is, for example, not less than 2 and not more than 60. The number n may be, for example, 16 or more. The number n may be, for example, about 30. The number n may be, for example, 30 or less.

Each of the multiple stacked bodies SL includes a first layer 41, a second layer 42, and a third layer 43.

The first layer 41 includes Inₓ₁Ga₁₋ₓ₁N (0<x1<1). The first layer 41 includes, for example, InGaN. For example, the In composition ratio x1 is not less than 0.02 and not more than 0.15.

The second layer 42 is provided between the first layer 41 and the light emitting layer 30 to contact the first layer 41. The second layer 42 includes Al_{y1}Ga_{1-y1}N (0<y1<1). The second layer 42 includes, for example, AlGaN. For example, the Al composition ratio y1 is not less than 0.005 and not more than 0.02.

The third layer 43 is provided between the second layer 42 and the light emitting layer 30 to contact the second layer 42. The third layer 43 includes Al_{y2}Ga_{1-y2}N (0≦y2<y1). The Al composition ratio of the third layer 43 is lower than the Al composition ratio of the second layer 42. For example, the Al composition ratio y2 is not less than 0 but less than 0.005. The third layer 43 includes, for example, GaN. Hereinbelow, the case is described where the third layer 43 includes GaN.

Thus, each of the multiple stacked bodies SL provided in the first intermediate unit 40 has a stacked structure of the first layer 41, the second layer 42, and the third layer 43. The material is substantially the same for the first layers 41 in the multiple stacked bodies SL. In other words, the In composition ratio x1 is substantially constant in the multiple stacked bodies SL. The Al composition ratio y1 is substantially constant in the multiple stacked bodies SL. The Al composition ratio y2 is substantially constant in the multiple stacked bodies SL. For example, the third layer 43 includes GaN in the multiple stacked bodies SL.

For example, an average ax1 is the average of the In composition ratio x1 of the first layer 41 in the multiple stacked bodies SL. Fluctuation dx1 is the fluctuation of the In composition ratio x1 between the multiple stacked bodies SL. The fluctuation dx1 is the absolute value of the difference between the maximum value and the minimum value of the In composition ratio x1 in the multiple stacked bodies SL. The fluctuation dx1 is, for example, within plus or minus 15% of the average ax1. It is desirable to be within plus or minus 10%. It is more desirable to be within plus or minus 5%.

An average ay1 is the average of the Al composition ratio y1 of the second layer 42 in the multiple stacked bodies SL. Fluctuation dy1 is the fluctuation of the Al composition ratio y1 between the multiple stacked bodies SL. The fluctuation dy1 is the absolute value of the difference between the maximum value and the minimum value of the Al composition ratio y1 in the multiple stacked bodies SL. The fluctuation dy1 is, for example, within plus or minus 15% of the average ay1. It is desirable to be within plus or minus 10%. It is more desirable to be within plus or minus 5%.

An average ay2 is the average of the Al composition ratio y2 of the third layer 43 in the multiple stacked bodies SL. Fluctuation dy2 is the fluctuation of the Al composition ratio y2 between the multiple stacked bodies SL. The fluctuation dy2 is the absolute value of the difference between the maximum value and the minimum value of the Al composition ratio y2 in the multiple stacked bodies SL. The fluctuation dy2 is, for example, within plus or minus 15% of the average ay2. It is desirable to be within plus or minus 10%. It is more desirable to be within plus or minus 5%.

The thicknesses are substantially constant in the multiple stacked bodies SL for the first layer 41, the second layer 42, and the third layer 43. The thickness is the length along the Z-axis direction.

An average at1 is the average of a thickness t1 of the first layer 41 in the multiple stacked bodies SL. Fluctuation dt1 is the fluctuation of the thickness t1 between the multiple stacked bodies SL. The fluctuation dt1 is the absolute value of the difference between the maximum value and the minimum value of the thickness t1 in the multiple stacked bodies SL. The fluctuation dt1 is, for example, within plus or minus 15% of the average at1. It is desirable to be within plus or minus 10%. It is more desirable to be within plus or minus 5%.

An average at2 is the average of a thickness t2 of the second layer 42 in the multiple stacked bodies SL. Fluctuation dt2 is the fluctuation of the thickness t2 between the multiple stacked bodies SL. The fluctuation dt2 is the absolute value of the difference between the maximum value and the minimum value of the thickness t2 in the multiple stacked bodies SL. The fluctuation dt2 is, for example, within plus or minus 15% of the average at2. It is desirable to be within plus or minus 10%. It is more desirable to be within plus or minus 5%.

An average at3 is the average of a thickness t3 of the third layer 43 in the multiple stacked bodies SL. Fluctuation dt3 is the fluctuation of the thickness t3 between the multiple stacked bodies SL. The fluctuation dt3 is the absolute value of the difference between the maximum value and the minimum value of the thickness t3 in the multiple stacked bodies SL. The fluctuation dt3 is, for example, within plus or minus 15% of the average at3. It is desirable to be within plus or minus 10%. It is more desirable to be within plus or minus 5%.

In the embodiment, it is favorable for the thickness t2 of the second layer 42 to be the thickness t1 of the first layer 41 or less. It is favorable for the thickness t2 of the second layer 42 to be thinner than the thickness t3 of the third layer 43. Thereby, spiral growth in the first intermediate unit 40 and the light emitting layer 30 is suppressed; and nonuniformity of the light emission distribution is improved.

The thickness t1 of the first layer 41 is, for example, not less than 0.9 nanometers and not more than 1.1 nanometers.

The thickness t2 of the second layer 42 is, for example, not less than 0.9 nanometers and not more than 1.1 nanometers.

The thickness t3 of the third layer 43 is, for example, not less than 1.8 nanometers and not more than 2.2 nanometers.

For example, the first semiconductor layer 10, the first intermediate unit 40, the light emitting layer 30, and the second semiconductor layer 20 recited above are formed on a silicon substrate 80. The plane orientation of the silicon substrate 80 is, for example, the (111) plane. However, in the embodiment, the plane orientation is arbitrary.

For example, a buffer layer 50 is provided on the silicon substrate 80. A low impurity concentration layer 10i is provided on the buffer layer 50. The first semiconductor layer 10, the first intermediate unit 40, the light emitting layer 30, and the second semiconductor layer 20 are provided in this order on the low impurity concentration layer 10i. The concentration of the impurity of the low impurity concentration layer 10i is lower than the concentration of the impurity of the first semiconductor layer 10. The low impurity concentration layer 10i includes, for example, undoped GaN. The low impurity concentration layer 10i is provided as necessary and may be omitted.

These layers are formed on the silicon substrate 80 by epitaxial growth.

For example, the semiconductor light emitting element 110 includes the first semiconductor layer 10 of the first conductivity type that is formed on the silicon substrate 80, the first intermediate unit 40 that is provided on the first semiconductor layer 10, the light emitting layer 30 that is provided on the first intermediate unit 40, and the second semiconductor layer 20 of the second conductivity type that is provided on the light emitting layer 30. The light emitting layer 30 includes the well layer 32; and the well layer 32 includes a nitride semiconductor including In. The first intermediate unit 40 includes the multiple stacked bodies SL1 to SLn recited above. The multiple stacked bodies SL1 to SLn are arranged in the first direction (the Z-axis direction) from the first semiconductor layer 10 toward the second semiconductor layer 20. Each of the multiple stacked bodies SL includes the first layer 41, the second layer 42, and the third layer 43 recited above.

An example of the buffer layer 50 will now be described.

FIG. 2 is a schematic cross-sectional view illustrating a portion of the semiconductor light emitting element according to the first embodiment. As shown in FIG. 2, the buffer layer 50 is provided on the silicon substrate 80; and the first semiconductor layer 10 (or the low impurity concentration layer 10i) is provided on the buffer layer 50.

The buffer layer 50 includes an AlN layer 51, an AlGaN buffer layer 52, a GaN layer 53, and an Al-containing layer 54.

The AlN layer 51 is provided on the silicon substrate 80. The AlN layer 51 is a high temperature growth AlN layer. By providing the AlN layer 51, reactions between the silicon substrate 80 and the layers on the AlN layer 51 are suppressed.

The AlGaN buffer layer 52 is provided on the AlN layer 51. The GaN layer 53 is provided on the AlGaN buffer layer 52. The Al-containing layer 54 is provided on the GaN layer 53. In the example, multiple sets of the combination of the GaN layer 53 and the Al-containing layer 54 are provided. For example, excessive stress may be applied to the nitride semiconductor layer due to the difference between the coefficients of thermal expansion of the silicon substrate 80 and the nitride semiconductor layer, etc. For example, the stress is adjusted by the combination of the GaN layer 53 and the AI-containing layer 54. The Al-containing layer 54 has, for example, the stacked structure of the AlGaN layer and the AlN layer. The AlN layer is formed by low temperature growth.

An example of the light emitting layer 30 will now be described.

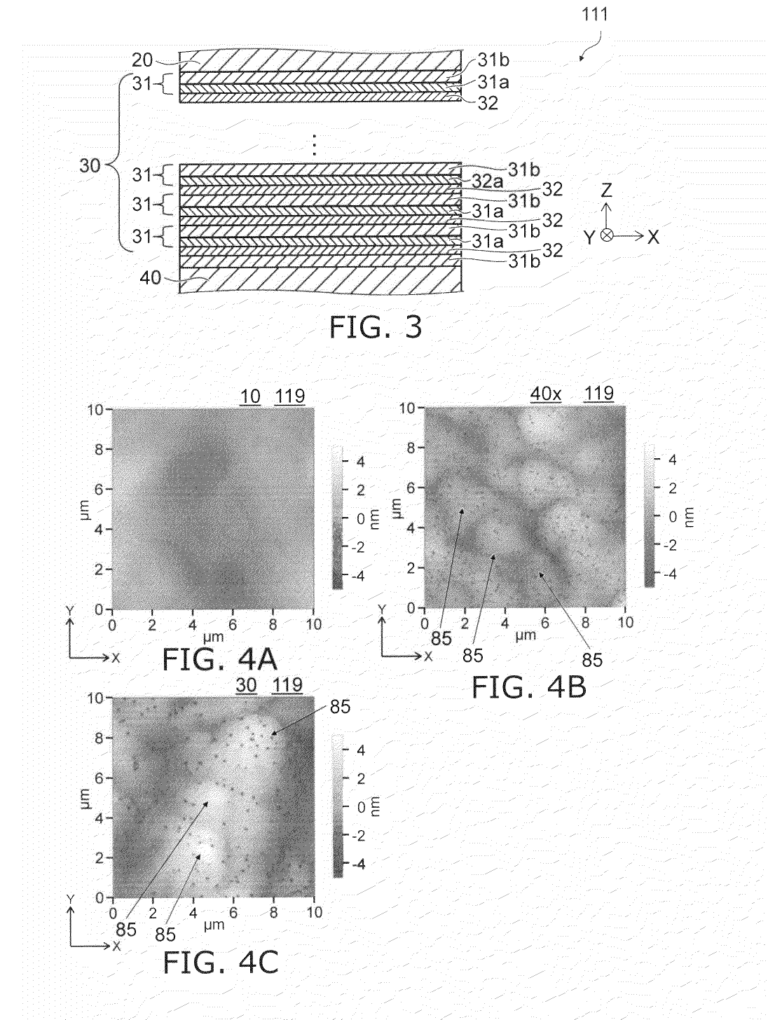

FIG. 3 is a schematic cross-sectional view illustrating a portion of the semiconductor light emitting element according to the first embodiment. As shown in FIG. 3, in addition to the well layer 32, the light emitting layer 30 further includes a barrier layer 31. The well layer 32 is disposed between two barrier layers 31. In the example, the light emitting layer 30 has a multiple quantum well (MQW) configuration. In other words, the light emitting layer 30 includes the multiple well layers 32 and the multiple barrier layers 31. The multiple well layers 32 are disposed respectively in the spaces between the barrier layers 31. In the embodiment, the light emitting layer 30 may have a single quantum well (SQW) configuration. In such a case, the number of well layers 32 is 1.

The bandgap energy of the barrier layer 31 is larger than the bandgap energy of the well layer 32. As described above, the well layer includes In_{w1}Ga_{1-w1}N (0<w1<1); and the barrier layer 31 includes, for example, GaN, AlGaN, etc.

In the semiconductor light emitting element 111 illustrated in FIG. 3, the barrier layer 31 has a stacked structure of multiple layers. In other words, one barrier layer 31 includes multiple regions having different compositions.

In other words, the light emitting layer 30 includes, for example, a first barrier region 31a and a second barrier region 31b.

The first barrier region 31a is provided between the well layer 32 and the second semiconductor layer 20 to contact the well layer 32. The first barrier region 31a includes Al_{b1}Ga_{1-b1}N (0<b1≦1). The first barrier region 31a includes, for example, AlGaN.

The second barrier region 31b is provided between the first barrier region 31a and the second semiconductor layer 20 to contact the first barrier region 31a. The second barrier region 31b includes Al_{b2}Ga_{1-b2}N (0≦b2<b1). The second barrier region 31b includes, for example, GaN. The case will now be described where GaN is used as the second barrier region 31b.

The first barrier region 31a and the second barrier region 31b are included in one barrier layer 31. In the embodiment, the composition may be substantially constant in one barrier layer 31.

In the semiconductor light emitting element 110 according to the embodiment, the composition is substantially constant in one barrier layer 31. In the semiconductor light emitting element 110, GaN is used as the barrier layer 31. In such a case, a stacked structure of the two layers of an InGaN layer (the well layer 32)/GaN layer (the barrier layer 31) is employed in the light emitting layer 30. Such a stacked structure is multiply provided.

On the other hand, in the semiconductor light emitting element 111 according to the embodiment, the first barrier region 31a and the second barrier region 31b are provided in one barrier layer 31. In such a case, a stacked structure of three layers of an InGaN layer (the well layer 32)/AlGaN layer (the first barrier region 31a)/GaN layer (the second barrier region 31b) is employed in the light emitting layer 30. Such a stacked structure is multiply provided.

The first intermediate unit 40 recited above is provided in the semiconductor light emitting elements 110 and 111 according to the embodiment. A stacked structure of the three layers of an InGaN layer (the first layer 41)/AlGaN layer (the second layer 42)/GaN layer (the third layer 43) is employed in each of the multiple stacked bodies SL included in the first intermediate unit 40. The first intermediate unit 40 has, for example, a superlattice structure.

In a general superlattice structure, two types of films are disposed alternately. Conversely, in the embodiment, the luminous efficiency can be increased by using a stacked structure of the three layers of the InGaN layer/AlGaN layer/GaN layer.

For example, in the embodiment, the growth having a spiral configuration that occurs in the first intermediate unit 40 including the InGaN layer is suppressed. The crystal grain boundaries of the first intermediate unit 40 decrease. Thereby, the crystal grain boundaries in the light emitting layer 30 including the InGaN layer decrease. According to the embodiment, the luminous efficiency can be increased.

For example, the nitride semiconductor that includes In grows two-dimensionally by atomic steps being wound in a spiral configuration. In other words, spiral growth occurs. Many crystal grain boundaries occur as the crystals having the spiral growth collide. As described below, the crystal grain boundaries occur markedly in the case where the screw dislocation density is high.

Defects exist at the crystal grain boundaries. The crystal grain boundaries cause the luminous efficiency of the semiconductor light emitting element to decrease. There are cases where a portion of the nitride semiconductor layer including In vanishes due to the spiral growth; and vanishing regions occur. When vanishing regions occur, regions occur where the luminous efficiency of the semiconductor light emitting element is low. In the light emission luminance distribution, portions (dark spots) having sizes of about 50 μm occur where the luminance is low. Thereby, the luminous efficiency decreases.

By using the stacked structure of the three layers of the InGaN layer/AlGaN layer/GaN layer in the embodiment, the spiral growth is suppressed; the vanishing regions of the nitride semiconductor layer including In are suppressed; and the dark spots are suppressed. Thereby, the luminous efficiency can be increased.

An example of experimental results of the crystal grain boundaries of the semiconductor light emitting element will now be described.

In the experiment, the buffer layer 50, the low impurity concentration layer 10i, the first semiconductor layer 10, the first intermediate unit 40, the light emitting layer 30, and the second semiconductor layer 20 are epitaxially grown sequentially on the silicon substrate 80. The conditions of the formation of these layers are as follows.

First, 210 nm of an AlN layer at 1070° C., 200 nm of an Al_{0.5}Ga_{0.5}N layer, 250 nm of an Al_{0.3}Ga_{0.7}N layer, and 350 nm of an Al_{0.15}Ga_{0.85}N layer at 1050° C. are formed in this order as the buffer layer 50.

Continuing, 1000 nm of a GaN layer is formed at 1060° C. as the low impurity concentration layer 10i.

Continuing, 1000 nm of a Si-doped GaN layer is formed at 1060° C. as the first semiconductor layer 10.

Then, 30 periods of the combination of 1.0 nm of an InGaN layer, 1.0 nm of an AlGaN layer, and 2.0 nm of a GaN layer are formed as the first intermediate unit 40. The temperature of the formation is 840° C. The growth rate is about 1.75 nm/min. The In composition ratio of the InGaN layer is 8%. The Al composition ratio of the AlGaN layer is 1.5%.

The well layer 32 and the barrier layer 31 are formed as the light emitting layer 30 after growing the first intermediate unit 40. In other words, 3.5 nm of an InGaN layer used to form the well layer 32 is formed at 800° C. 1.0 nm of a first GaN layer that is used to form a portion of the barrier layer 31 is formed at 800° C. 1.5 nm of a second GaN layer that is used to form another portion of the barrier layer 31 is formed at 850° C. on the first GaN layer. 0.5 nm of a third GaN layer that is used to form another portion of the barrier layer 31 is formed at 800° C. on the second GaN layer. The thickness of one barrier layer 31 is 3.0 nm. The formation of the combination of the well layer 32 and the barrier layer 31 recited above is repeated eight times. Thereby, the light emitting layer 30 is formed.

5 nm of a Mg-doped AlGaN layer, 80 nm of a Mg-doped GaN layer, and 5 nm of a Mg-doped GaN contact layer are formed in this order as the second semiconductor layer 20 on the light emitting layer 30. Thereby, the semiconductor light emitting element 110 is obtained.

As recited above, the semiconductor light emitting element 111 is obtained by changing the formation conditions of the light emitting layer 30. Namely, in the semiconductor light emitting element 111, the stacked film of the AlGaN layer and the GaN layer is used as the barrier layer 31. In such a case, after forming an InGaN layer used to form the well layer 32 at 800° C., 1.0 nm of an AlGaN layer used to form a portion of the barrier layer 31 is formed at 800° C.; 1.5 nm of a GaN layer used to form another portion of the barrier layer 31 is formed at 850° C.; and 0.5 nm of a GaN layer used to form another portion of the barrier layer 31 is formed at 800° C. In the experiment, the formation of the combination of the well layer 32 and the barrier layer 31 is repeated eight times. The growth rate is about 1.30 nm/min. The In composition ratio of the InGaN layer used to form the well layer 32 is 14%. The Al composition ratio of the AlGaN layer recited above that is used to form the portion of the barrier layer 31 is 15.0%. The other conditions are similar to those of the semiconductor light emitting element 110.

In the experiment, in addition to the semiconductor light emitting element according to the embodiment, a semiconductor light emitting element of a reference example also is made. As recited above, in the semiconductor light emitting element according to the embodiment, the stacked structure of the three layers of the InGaN layer/AlGaN layer/GaN layer recited above is formed as the first intermediate unit 40. On the other hand, in the semiconductor light emitting element of the reference example, an intermediate unit having a stacked structure of two layers of an InGaN layer/GaN layer is formed instead of the first intermediate unit 40. Other than the AlGaN layer not being formed, the formation conditions of the stacked structure of the two layers of the InGaN layer/GaN layer are similar to the formation conditions of the stacked structure of the three layers recited above.

FIG. 4A to FIG. 4C are atomic force microscope images illustrating the semiconductor light emitting element of a first reference example.

These drawings are atomic force microscope (AFM) images of the semiconductor light emitting element 119 of the first reference example. In the first reference example, the light emitting layer 30 includes a stacked structure of two layers of an InGaN layer/GaN layer. FIG. 4A is an AFM image of the front surface of the first semiconductor layer 10. FIG. 4B is an AFM image of the front surface of an intermediate unit 40x (InGaN layer/GaN layer). FIG. 4C is an AFM image of the front surface of the light emitting layer 30 (the InGaN layer/GaN layer).

It can be seen from FIG. 4B and FIG. 4C that many regions (small domains 85) having circular configurations (elliptical configurations) are observed in the light emitting layer 30 and the intermediate unit 40x including the InGaN layer. The size (e.g., the diameter) of the small domains 85 is about 2 μm.

As shown in FIG. 4A, the small domains 85 are not observed in the first semiconductor layer 10 of GaN. Therefore, it is considered that the occurrence of the small domains 85 is unique to the InGaN layer. It is considered that the small domains 85 occur due to the spiral growth in the InGaN layer. The boundaries between the small domains 85 correspond to the crystal grain boundaries. The size (e.g., the diameter) of the crystal grain is about 2 μm.

Comparing FIG. 4B and FIG. 4C, the spiral growth is enhanced further in the light emitting layer 30. The growth mode of the light emitting layer 30 is strongly affected by the small domains 85 formed in the intermediate unit 40x by the spiral growth. It is considered that the spiral growth in the light emitting layer 30 can be suppressed by suppressing the spiral growth in the intermediate unit 40x.

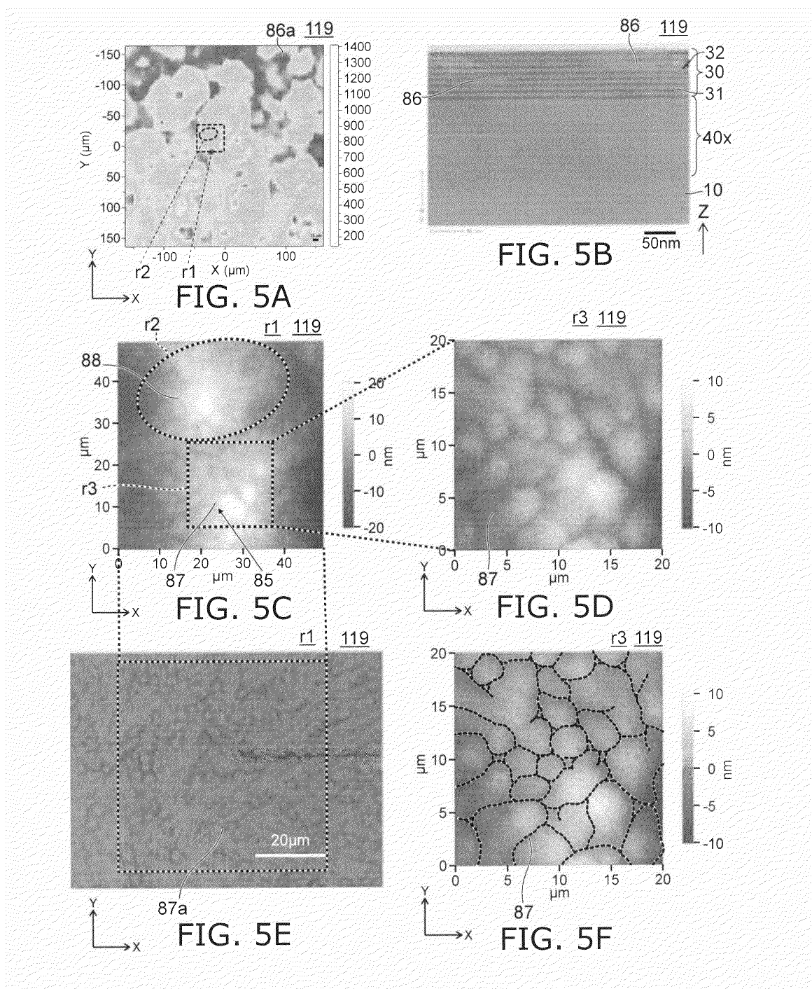

FIG. 5A to FIG. 5F are micrographs illustrating the semiconductor light emitting element of the first reference example. These drawings correspond to the semiconductor light emitting element 119 of the first reference example. FIG. 5A is a micro photoluminescence image. FIG. 5B is a transmission electron microscope photograph showing the cross section of the semiconductor light emitting element 119. Region r1 and region r2 are shown in FIG. 5A. FIG. 5C is an AFM image corresponding to region r1 shown in FIG. 5A. FIG. 5D is an AFM image showing an enlargement of region r3 shown in FIG. 5C. FIG. 5E is a fluorescence microscope image of a region including region r1. In FIG. 5F, broken lines that illustrate the grain boundaries are added to the AFM image shown in FIG. 5D.

As shown in FIG. 5B, it can be seen that a portion of the well layer 32 of InGaN has vanished inside the light emitting layer 30. In other words, unformed regions 86 (vanishing regions) occur in the InGaN layer. The unformed regions 86 correspond to dark spots 86a shown in FIG. 5A.

Comparing FIG. 5C, FIG. 5D, FIG. 5F, and FIG. 5E, it can be seen that crystal grain boundaries 87 observed in the AFM images of FIG. 5C, FIG. 5D, and FIG. 5F correspond to dark lines 87a observed in the fluorescence microscopy of FIG. 5E. The crystal grain boundaries 87 correspond to the boundaries of the small domains 85. As shown in FIG. 5C, the multiple small domains 85 form a large domain 88. The size of the large domain 88 is about 30 μm to 50 μm. The large domain 88 corresponds to the light emission distribution of the micro photoluminescence image shown in FIG. 5A.

Thus, in the semiconductor light emitting element 119 of the first reference example, the light emission distribution is nonuniform in the micro photoluminescence image (FIG. 5A). Also, in the micro photoluminescence image, the InGaN layer (the well layer 32) is observed to vanish in the regions (the dark spots 86a) where the luminous efficiency is markedly low. In other words, the unformed regions 86 occur. It is considered that the unformed regions 86 occur due to the spiral growth.

As described above, the boundaries of the small domains 85 (the crystal grain boundaries 87 observed in the AFM images) correspond to the dark lines 87a observed in the fluorescence microscope. When there are many crystal grain boundaries 87, the light emission luminance decreases at the crystal grain boundaries 87. In other words, having few dark lines 87a observed in the fluorescence microscope image is linked to having a high light emission luminance. Also, having few dark lines 87a corresponds to having few regions of low luminance and having a uniform light emission distribution.

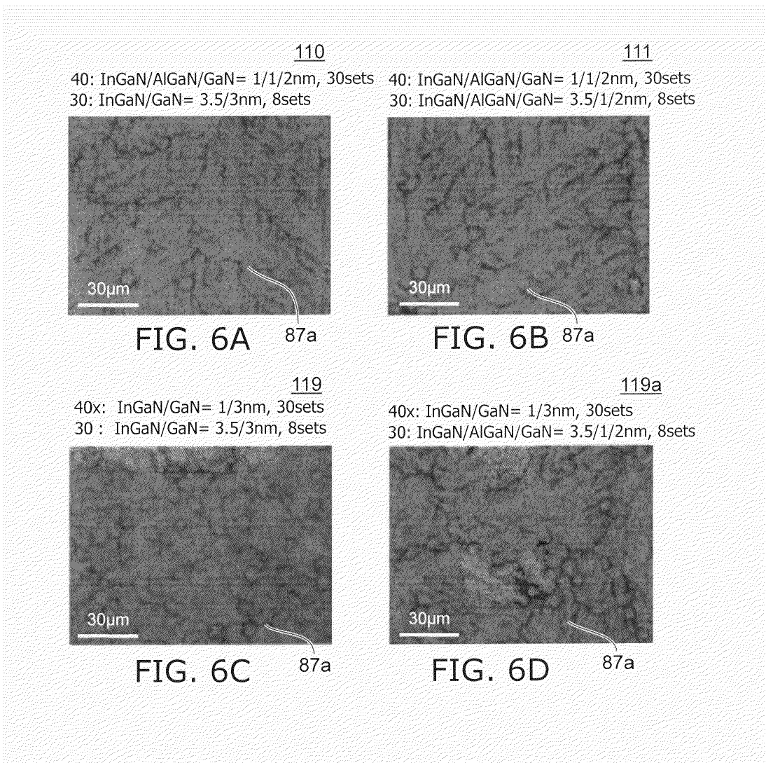

FIG. 6A to FIG. 6D are schematic views illustrating characteristics of the semiconductor light emitting elements.

These drawings are fluorescence microscope images. FIG. 5A corresponds to the semiconductor light emitting element 110 according to the embodiment. FIG. 5B corresponds to the semiconductor light emitting element 111 according to the embodiment. FIG. 5C corresponds to the semiconductor light emitting element 119 of the first reference example. FIG. 5D corresponds to a semiconductor light emitting element 119a of a second reference example.

In the semiconductor light emitting element 110, the first intermediate unit 40 has a stacked structure of three layers of an InGaN layer/AlGaN layer/GaN layer. In the first intermediate unit 40, the thickness of the InGaN layer (having an In composition ratio of 0.08) is about 1 nm. In the first intermediate unit 40, the thickness of the AlGaN layer (having an Al composition ratio of 0.015) is about 1 nm. In the first intermediate unit 40, the thickness of the GaN layer is 2 nm. In the first intermediate unit 40, the number of sets of the InGaN layer/AlGaN layer/GaN layer is 30. The light emitting layer 30 has a stacked structure of two layers of an InGaN layer/GaN layer. In the light emitting layer 30, the thickness of the InGaN layer (having an In composition ratio of 0.14) is about 3.5 nm. In the light emitting layer 30, the thickness of the GaN layer is about 3 nm. In the light emitting layer 30, the number of sets of the InGaN layer/GaN layer is 8.

In the semiconductor light emitting element 111, the configuration of the first intermediate unit 40 is the same as that of the semiconductor light emitting element 110. In the semiconductor light emitting element 111, the light emitting layer 30 has a stacked structure of three layers of an InGaN layer/AlGaN layer/GaN layer. In the light emitting layer 30, the thickness of the InGaN layer (having an In composition ratio of 0.14) is about 3.5 nm. In the light emitting layer 30, the thickness of the AlGaN layer (having an Al composition ratio of 0.15) is about 1 nm. In the light emitting layer 30, the thickness of the GaN layer is about 2 nm. In the light emitting layer 30, the number of sets of the InGaN layer/AlGaN layer/GaN layer is 8.

In the semiconductor light emitting element 119 of the first reference example, the intermediate unit 40x has a stacked structure of two layers of an InGaN layer/GaN layer. In the intermediate unit 40x, the thickness of the InGaN layer (having an In composition ratio of 0.08) is about 1 nm. In the first intermediate unit 40, the thickness of the GaN layer is 3 nm. In the intermediate unit 40x, the number of sets of the InGaN layer/GaN layer is 30. In the semiconductor light emitting element 119, the configuration of the light emitting layer 30 is the same as that of the semiconductor light emitting element 110.

In the semiconductor light emitting element 119a of the second reference example, the configuration of the first intermediate unit 40 is the same as that of the semiconductor light emitting element 119. In the semiconductor light emitting element 119a, the configuration of the light emitting layer 30 is the same as that of the semiconductor light emitting element 111.

As shown in FIG. 6C and FIG. 6D, many dark lines 87a are observed in the semiconductor light emitting elements 119 and 119a of the first and second reference examples. This corresponds to many boundaries of the small domains 85 (the crystal grain boundaries 87 observed in the AFM images).

There are few dark lines 87a in the semiconductor light emitting elements 110 and 111 according to the embodiment as shown in FIG. 6A and FIG. 6B. In particular, the dark lines 87a are extremely few in the semiconductor light emitting element 111. This corresponds to having few boundaries of the small domains 85 (crystal grain boundaries 87 observed in the AFM images).

It is considered that the growth mode of the GaN layer grown on the AlGaN layer changed because the AlGaN layer is grown on the InGaN layer having the spiral growth. It is considered the spiral growth is suppressed in the GaN layer. Thereby, it is considered that the dark lines 87a decreased.

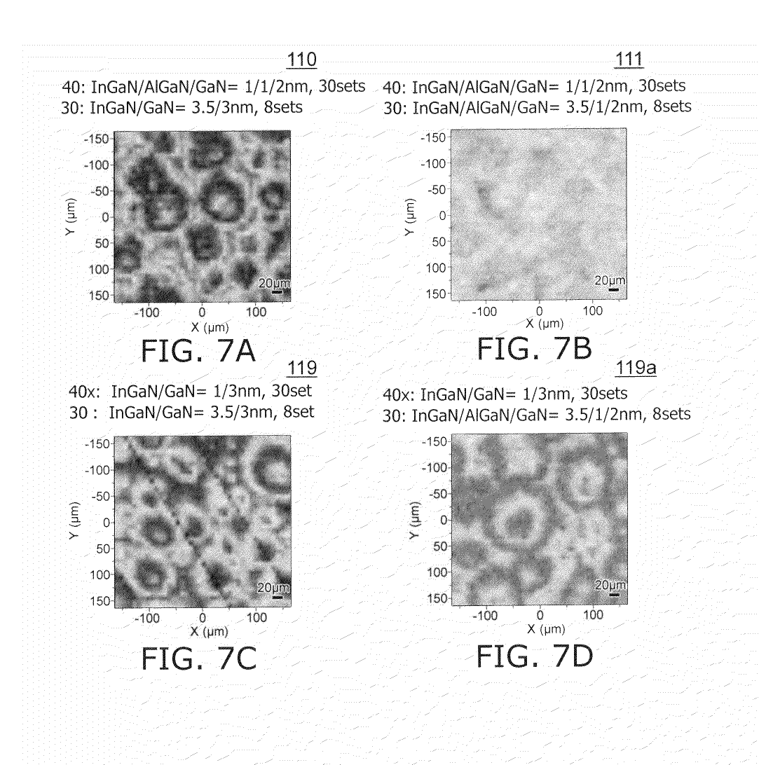

FIG. 7A to FIG. 7D are schematic views illustrating characteristics of the semiconductor light emitting elements.

These drawings are micro photoluminescence images. FIG. 5A to FIG. 5D correspond to the semiconductor light emitting elements 110, 111, 119, and 119a, respectively.

In the semiconductor light emitting element 119 of the first reference example as shown in FIG. 7C, the luminous efficiency in the micro photoluminescence image is low. There are regions where the luminance is markedly low; and the fluctuation of the planar distribution of the luminous efficiency is large. The median of the intensity (the luminance) in the plane is about 480 (arbitrary units); the maximum value of the intensity in the plane is about 780 (arbitrary units); and the minimum value of the intensity in the plane is about 180 (arbitrary units).

In the semiconductor light emitting element 119a of the second reference example as shown in FIG. 7D, compared to the semiconductor light emitting element 119, the luminous efficiency is higher; but the fluctuation of the planar distribution is large. The median of the intensity (the luminance) in the plane in about 530 (arbitrary units); the maximum value of the intensity in the plane is about 730 (arbitrary units); and the minimum value of the intensity in the plane is about 390 (arbitrary units).

In the semiconductor light emitting element 110 according to the embodiment as shown in FIG. 7A, compared to the semiconductor light emitting element 119, the luminous efficiency is higher; and the fluctuation of the planar distribution is small. The median of the intensity (the luminance) in the plane is about 530 (arbitrary units); the maximum value of the intensity in the plane is about 650 (arbitrary units); and the minimum value of the intensity in the plane is about 400 (arbitrary units).

In the semiconductor light emitting element 111 according to the embodiment as shown in FIG. 7B, the luminous efficiency is even higher than that of the semiconductor light emitting element 110; and the fluctuation of the planar distribution is small as well. The median of the intensity (the luminance) in the plane is about 570 (arbitrary units); the maximum value of the intensity in the plane is about 670 (arbitrary units); and the minimum value of the intensity in the plane is about 480 (arbitrary units).

Thus, by applying the stacked structure of the three layers of the InGaN layer/AlGaN layer/GaN layer as the first intermediate unit 40, the luminous efficiency is increased; and the planar distribution is uniform. The luminous efficiency is increased further by applying the stacked structure of the three layers of the InGaN layer/AlGaN layer/GaN layer also to the light emitting layer 30.

In the multiple stacked bodies SL of the first intermediate unit 40 of the embodiment, the second layer 42 of AlGaN is formed on the first layer 41 of InGaN. Then, the third layer 43 of GaN is formed on the second layer 42. Even when the spiral growth of the first layer 41 of InGaN occurs, the spiral growth being inherited into the third layer 43 is suppressed by providing the second layer 42 of AlGaN. Thereby, the dark spots 86a, i.e., the vanishing of the InGaN layer, that is due to the spiral growth is suppressed.

The dark spots 86a that are described in the experiment recited above are not observed in the case where a nitride semiconductor layer including In is grown on a sapphire substrate. The dark spots 86a are observed uniquely in the case where the nitride semiconductor layer including In is grown on the silicon substrate 80. In other words, it is considered that the defects due to the spiral growth occur markedly when the screw dislocation density is high.

The screw dislocation density will now be described.

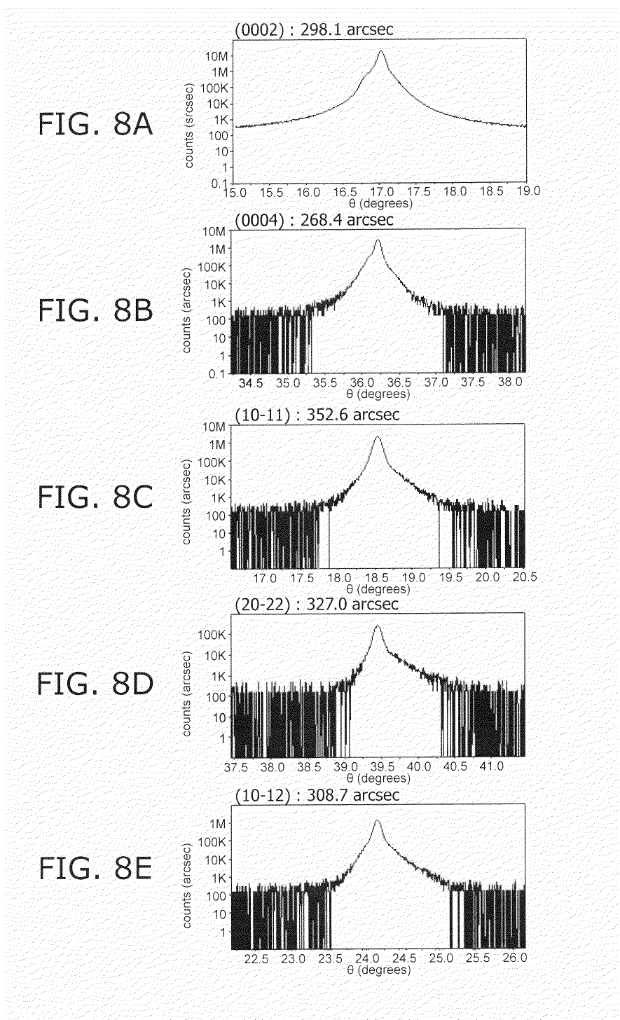

FIG. 8A to FIG. 8E are graphs of characteristics of the semiconductor light emitting element.

FIG. 8A to FIG. 8E show the X-ray rocking curves of the (0002) plane, the (0004) plane, the (10-11) plane, the (20-22) plane, and the (10-12) plane, respectively. In these drawings, the horizontal axis is an angle θ (degrees) of the X-ray diffraction analysis. The vertical axis is the detection intensity counts (arcsec).

The screw dislocation density and the edge dislocation density are determined by the following first to fourth formulas using the full width at half maximums of the X-ray rocking curves of the (0002) plane, the (0004) plane, the (10-11) plane, and the (20-22) plane.

$$\begin{matrix}{D}_{screw} \frac{{β}_{m}^{2} ( tilt )}{4.36 {b}_{screw}^{2}} & ( 1 ) \\ {β}_{m} ( tilt ) = \sqrt{\begin{matrix}( {( \frac{2 π}{{d}_{0004}} \times {β}_{m} ( 0004 ) )}^{2} - {( \frac{2 π}{{d}_{0002}} \times {β}_{m} ( 0002 ) )}^{2} ) / \\ ( {( \frac{2 π}{{d}_{0004}} )}^{2} - {( \frac{2 π}{{d}_{0002}} )}^{2} )\end{matrix}} & ( 2 )\end{matrix}$$

The parameters recited above are as follows.

D_{screw} is the screw dislocation density (1/cm²).

βₘ(tilt) is the tilt angle (° (degrees)) of GaN corresponding to the screw dislocation component.

b_{screw} is the Burgers vector of the screw dislocation and is, for example, 0.519 nm.

βₘ(0002) is the full width at half maximum (°) of the (0002) plane.

βₘ(0004) is the full width at half maximum)(°) of the (0004) plane.

d₀₀₀₂ is the lattice plane spacing of the (0002) plane of GaN and is, for example, 2.597 angstroms.

d₀₀₀₄ is the lattice plane spacing of the (0004) plane of GaN and is, for example, 1.299 angstroms.

2π/d₀₀₀₂ is the lattice plane spacing of the reciprocal lattice space of the (0002) plane of GaN and is, for example, 2.4192 (1/angstrom).

2π/d₀₀₀₄ is the lattice plane spacing of the reciprocal lattice space of the (0004) plane of GaN and is, for example, 4.8384 (1/angstrom).

$$\begin{matrix}{D}_{edge} = \frac{{β}_{m}^{2} ( twist )}{4.36 {b}_{edge}^{2}} & ( 3 ) \\ {β}_{m} ( twist ) = \frac{\sqrt{\begin{matrix}( {( \frac{2 π}{{d}_{20 - 22}} \times {β}_{m} ( 20 - 22 ) )}^{2} - {( \frac{2 π}{{d}_{10 - 11}} \times {β}_{m} ( 10 - 11 ) )}^{2} ) \text{/} \\ ( {( \frac{2 π}{{d}_{20 - 22}} )}^{2} - {( \frac{2 π}{{d}_{10 - 11}} )}^{2} ) - {( {β}_{m} ( tilt ) \times cos ( \frac{X \times π}{180} ) )}^{2}\end{matrix}}}{sin ( \frac{X \times π}{180} )} & ( 4 )\end{matrix}$$

The parameters recited above are as follows.

D_{edge} is the edge dislocation density (1/cm²).

βₘ(twist) is the twist angle (° (degrees)) of GaN corresponding to the edge dislocation component. b_{edge} is the Burgers vector of the edge dislocation of GaN and is, for example, 0.319 nm.

βₘ(10-11) is the full width at half maximum)(°) of the (10-11) plane.

βₘ(20-22) is the full width at half maximum)(°) of the (20-22) plane.

d₁₀₋₁₁ is the lattice plane spacing of the (10-11) plane of GaN and is, for example, 2.437 angstroms.

d₂₀₋₂₂ is the lattice plane spacing of the (20-22) plane of GaN and is, for example, 1.218 angstroms.

2π/d₁₀₋₁₁ is the lattice plane spacing of the reciprocal lattice space of the (10-11) plane of GaN and is, for example, 2.5785 (1/angstrom).

2π/d₂₀₋₂₂ is the lattice plane spacing of the reciprocal lattice space of the (20-22) plane of GaN and is, for example, 5.1571 (1/angstrom).

X is the angle between the (10-11) plane and the normal direction of the front surface of the layer and is, for example, 62.02387°. X corresponds to the angle between the (20-22) plane and the normal direction of the front surface of the layer.

The screw dislocation density is calculated from the width at half maximums of the X-ray rocking curves of the (0002) plane and the (0004) plane. In the semiconductor light emitting elements 110 and 111, the edge dislocation density of the first semiconductor layer 10 is not less than about 4.6×10⁸/cm² and not more than about 5.9×10⁸/cm². In the semiconductor light emitting elements 119 and 119a, the edge dislocation density of the first semiconductor layer 10 is not less than about 4.4×10⁸/cm² and not more than about 5.3×10⁸/cm².

On the other hand, the edge dislocation density is calculated from the width at half maximums of the X-ray rocking curves of the (0002) plane, the (0004) plane, the (10-11) plane, and the (20-22) plane. In the semiconductor light emitting elements 110 and 111, the screw dislocation density of the first semiconductor layer 10 is not less than 1.3×10⁸/cm² and not less than 1.5×10⁸/cm². In the semiconductor light emitting elements 119 and 119a, the screw dislocation density of the first semiconductor layer 10 is about 1.4×10⁸/cm².

In the experiment, each of the layers is grown on the silicon substrate 80. In other words, the value of the screw dislocation density and the value of the edge dislocation density recited above are the values of the dislocation densities of the samples in which the nitride semiconductor layer is grown on the silicon substrate 80.

On the other hand, generally, the edge dislocation density of GaN grown on a sapphire substrate is about 1×10⁸/cm² to 9×10⁸/cm². The screw dislocation density of GaN grown on a sapphire substrate is about 1×10⁷/cm² to 9×10⁷/cm². In other words, for GaN grown on a sapphire substrate, the screw dislocation density is about 1/10 of the edge dislocation density.

Conversely, as recited above, the screw dislocation density for the samples grown on the silicon substrate 80 is not less than 1.3×10⁸/cm² and not less than 1.5×10⁸/cm² and is markedly high compared to the case where the growth is on the sapphire substrate. On the other hand, there is no large difference in the edge dislocation density between the case where the growth is on the silicon substrate 80 and the case where the growth is on the sapphire substrate.

In other words, it can be seen that the screw dislocation density is extremely high when the nitride semiconductor layer is grown on the silicon substrate 80. It is considered that this is a phenomenon unique to the semiconductor light emitting element grown on the silicon substrate 80.

Because the dark spots 86a are not observed when the nitride semiconductor layer including In is grown on the sapphire substrate but is observed uniquely when grown on the silicon substrate 80 as recited above, it is considered that the dark spots 86a occur uniquely when the screw dislocation density is high.

For example, when the silicon substrate 80 is used, the screw dislocation density is not less than 1.3×10⁸/cm² and not less than 1.5×10⁸/cm²; and the average is 1.4×10⁸/cm². On the other hand, the edge dislocation density is not less than about 4.4×10⁸/cm² and not more than about 5.9×10⁸/cm²; and the average is 5.1×10⁸/cm². In other words, the ratio of the screw dislocation density to the edge dislocation density is about 0.27. Including fluctuation, the ratio of the screw dislocation density to the edge dislocation density is about 0.2 or more. The ratio of the screw dislocation density to the edge dislocation density is 0.4 or less.

On the other hand, when the sapphire substrate is used, the screw dislocation density is about 1×10⁷/cm² to 9×10⁷/cm²; and the average is about 5×10⁷/cm². The edge dislocation density is about 1×10⁸/cm² to 9×10⁸/cm²; and the average is about 5×10⁸/cm². In other words, the ratio of the screw dislocation density to the edge dislocation density is about 0.1. Including fluctuation, the ratio of the screw dislocation density to the edge dislocation density is not less than about 0.02 but less than 0.2.

In the case where the screw dislocation density is high and the ratio of the screw dislocation density to the edge dislocation density is not less than about 0.2 and not more than 0.4, the dark spots 86a recited above occur uniquely. Accordingly, it is favorable to implement the first intermediate unit 40 according to the embodiment in the case where the screw dislocation density is high such as when the ratio of the screw dislocation density to the edge dislocation density is not less than about 0.2 and not more than about 0.4. Thereby, the effect of increasing the luminous efficiency is particularly high.

For example, when the sapphire substrate is used, the dark spots 86a that occur uniquely when using the silicon substrate 80 do not occur. The dark spots 86a caused by the spiral growth do not occur.

In the embodiment, by providing the AlGaN layer between the InGaN layer and the GaN layer, the spiral growth in the InGaN layer that occurs continuing from the GaN layer is suppressed. In the embodiment, the phenomenon of the dark spots 86a, etc., occurring uniquely when the silicon substrate 80 is used is suppressed.

For example, in the embodiment, the screw dislocation density of the first semiconductor layer 10 is 1×10⁸/cm² or more. For example, the screw dislocation density of the first semiconductor layer 10 is 1.3×10⁸/cm² or more. The screw dislocation density of the first semiconductor layer 10 is 5×10⁸/cm² or less. For example, the screw dislocation density of the first semiconductor layer 10 is 0.2 times the edge dislocation density of the first semiconductor layer 10 or more. Thus, in the case where the screw dislocation density is high, the effect of increasing the luminous efficiency becomes particularly high.

In such a case, the edge dislocation density is, for example, 6.0×10⁸/cm² or less. In the case where the edge dislocation density is excessively high, the effect of providing the first intermediate unit 40 is relatively small.

The screw dislocation density recited above is a value obtained from the rocking curve width at half maximum of the X-ray diffraction of the first semiconductor layer 10. The edge dislocation density also is a value obtained from the rocking curve width at half maximum of the X-ray diffraction of the first semiconductor layer 10.

In the first intermediate unit 40 according to the embodiment, it is desirable for the number of periods of the combination of the InGaN layer, the AlGaN layer, and the GaN layer to be 16 or more. In the case where the number of periods is less than 15, the expansion of the lattice in the in-plane direction of the first intermediate unit 40 is small; lattice relaxation occurs for the light emitting layer 30 in the in-plane direction with respect to the first intermediate unit 40; and there are cases where defects are introduced to the light emitting layer 30. Therefore, the light emission characteristics degrade. By setting the number of periods to be 16 or more, the defects are suppressed; and good light emission characteristics are obtained.

In the description of the semiconductor light emitting element 110 of the experiment recited above, the thickness of the first GaN layer (formed at 800° C.) of the light emitting layer 30 is 1.0 nm; the thickness of the second GaN layer (formed at 850° C.) is 1.5 nm; and the thickness of the third GaN layer (formed at 800° C.) is 0.5 nm. In the embodiment, the thickness of the second GaN layer may be thicker than 1.5 nm. In such a case, the thickness of the first GaN layer may be 1.0 nm; and the thickness of the third GaN layer may be 0.5 nm.

The lattice length in the plane (in the X-Y plane) of the first intermediate unit 40 expands in the case where the number of periods of the combination of the InGaN layer, the AlGaN layer, and the GaN layer in the first intermediate unit 40 is large. Thereby, the difference between the in-plane lattice lengths of the first intermediate unit 40 and the light emitting layer 30 can be reduced. The expansion of the in-plane lattice length of the first intermediate unit 40 decreases as the number of periods of the combination in the first intermediate unit 40 decreases. In such a case, lattice relaxation for the in-plane lattice length of the light emitting layer 30 easily occurs in the in-plane direction with respect to the in-plane lattice length of the first intermediate unit 40. Therefore, there is a tendency for defects to be introduced to the light emitting layer 30. Therefore, it is desirable for the number of periods of the combination in the first intermediate unit 40 to be large enough to maintain the crystal quality of the first intermediate unit 40. For example, from the perspective of characteristic improvement, it is desirable for the number of periods to be not less than 16 and not more than 60. From the perspective of production, it is desirable for the number of stacks to be small. Therefore, it is desirable for the number of periods of the combination in the first intermediate unit 40 to be not less than 16 and not more than 30.

### Second Embodiment

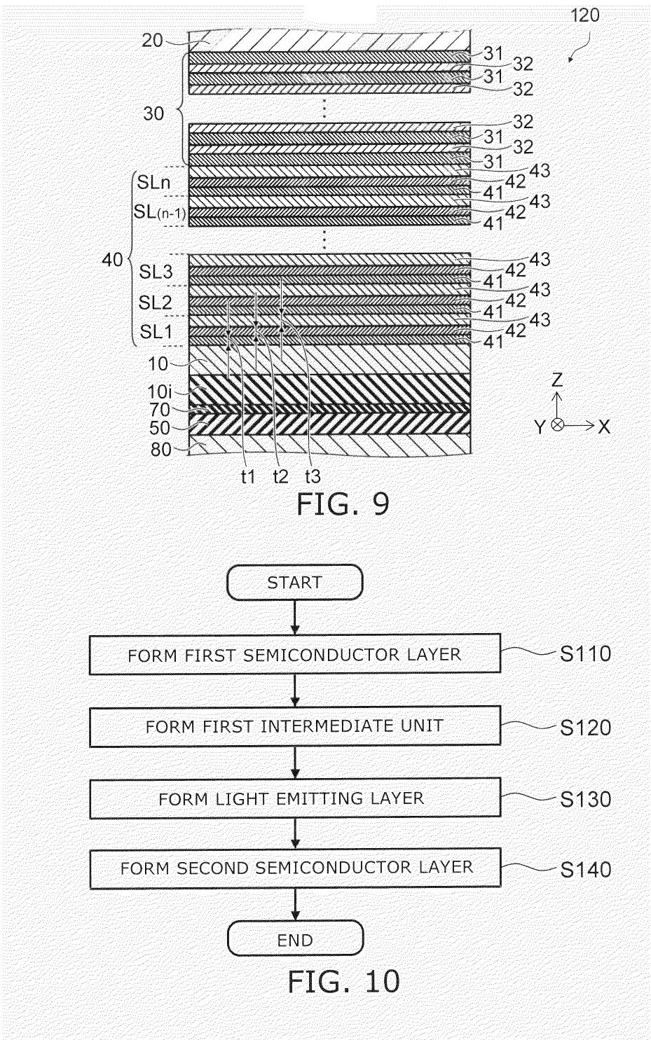

FIG. 9 is a schematic cross-sectional view illustrating a semiconductor light emitting element according to a second embodiment.

As shown in FIG. 9, the semiconductor light emitting element 120 according to the embodiment further includes a second intermediate unit 70 in addition to the first semiconductor layer 10, the second semiconductor layer 20, the light emitting layer 30, and the first intermediate unit 40. Otherwise, the semiconductor light emitting element 120 is similar to the semiconductor light emitting element 110; and a description is omitted. For example, in the semiconductor light emitting element 120 as well, the light emitting layer 30 may include the first barrier region 31a and the second barrier region 31b recited above. In the semiconductor light emitting element 120 as well, the composition may be substantially constant in one barrier layer 31.

The first semiconductor layer 10 is disposed between the second intermediate unit 70 and the first intermediate unit 40. For example, the buffer layer 50 is provided on the silicon substrate 80; and the second intermediate unit 70 is provided on the buffer layer 50. In the example, the low impurity concentration layer 10i is provided on the second intermediate unit 70; and the first semiconductor layer 10, the light emitting layer 30, and the second semiconductor layer 20 are provided in this order on the low impurity concentration layer 10i.

The second intermediate unit 70 includes a nitride including one of silicon, magnesium, or boron. The second intermediate unit 70 includes a nitride region including a nitride including one of silicon, magnesium, or boron. For example, the nitride region is not a nitride semiconductor. The second intermediate unit 70 includes, for example, at least one of SiN, MgN, or BN.

The thickness (the length in the Z-axis direction) of the nitride region of the second intermediate unit 70 is not less than 0.2 atomic layers and not more than 3 nanometers. For example, being 0.2 atomic layers thick corresponds to a thickness of about 0.05 nanometers.

By providing the second intermediate unit 70, the dislocation density can be low; and the crystal quality can be improved. In the case where the silicon substrate 80 is used, the screw dislocation density is higher than that of the case where the sapphire substrate is used even when the second intermediate unit 70 is used. Therefore, by using the first intermediate unit 40 according to the embodiment, the defects caused by the spiral growth are suppressed.

For example, the second intermediate unit 70 may have a stacked structure of a nitride region (a region including a nitride including one of silicon, magnesium, or boron) and a nitride semiconductor layer (e.g., a GaN layer). For example, the second intermediate unit 70 may have a stacked structure of a GaN layer and a nitride region of SiN. Further, the second intermediate unit 70 may include multiple nitride regions of SiN disposed alternately with multiple GaN layers.

### Third Embodiment

The embodiment relates to a method for manufacturing the semiconductor light emitting element.

FIG. 10 is a flowchart illustrating the method for manufacturing the semiconductor light emitting element according to the third embodiment.

As shown in FIG. 10, the first semiconductor layer 10 of the first conductivity type is formed on the silicon substrate 80 (step S110). The first intermediate unit 40 is formed on the first semiconductor layer 10 (step S120). The light emitting layer 30 that includes the well layer 32 including a nitride semiconductor including In is formed on the first intermediate unit 40 (step S130). The second semiconductor layer 20 of the second conductivity type is formed on the light emitting layer 30 (step S140).

The forming of the first intermediate unit 40 (step S120) includes forming the multiple stacked bodies SL. The multiple stacked bodies SL are arranged in a direction (the Z-axis direction from the first semiconductor layer 10 toward the second semiconductor layer 20) intersecting the major surface of the silicon substrate 80.

Each of the multiple stacked bodies SL includes the first layer 41, the second layer 42, and the third layer 43. The first layer 41 includes Inₓ₁Ga₁₋ₓ₁N (0<x1<1). The second layer 42 is provided in contact with the first layer 41 on the first layer 41. The second layer 42 includes Al_{y1}Ga₁₋ₓ₁N (0<y1<1). The third layer 43 is provided in contact with the second layer 42 on the second layer 42. The third layer 43 includes Al_{y2}Ga_{1-y2}N (0≦y2<y1).

According to the embodiment, a method for manufacturing a semiconductor light emitting element having high luminous efficiency can be provided.

In the embodiment, for example, the thickness t2 of the second layer 42 is not more than the thickness t1 of the first layer 41. The thickness t2 of the second layer 42 is thinner than the thickness t3 of the third layer 43.

For example, the fluctuation dt1 of the thickness t1 of the first layer 41 between the multiple stacked bodies SL is within plus or minus 15% of the average at1 of the thickness t1 of the first layer 41 in the multiple stacked bodies SL. The fluctuation dt2 of the thickness t2 of the second layer 42 between the multiple stacked bodies SL is within plus or minus 15% of the average at2 of the thickness t2 of the second layer 42 in the multiple stacked bodies SL. The fluctuation dt3 of the thickness t3 of the third layer 43 between the multiple stacked bodies SL is within plus or minus 15% of the average at3 of the thickness t3 of the third layer 43 in the multiple stacked bodies SL.

In the embodiment, the thickness t1 of the first layer 41 is not less than 0.9 nanometers and not more than 1.1 nanometers. The thickness t2 of the second layer 42 is not less than 0.9 nanometers and not more than 1.1 nanometers. The thickness t3 of the third layer 43 is not less than 1.8 nanometers and not more than 2.2 nanometers.

The fluctuation dx1 of the In composition ratio x1 of the first layer 41 between the multiple stacked bodies SL is within plus or minus 15% of the average ax1 of the In composition ratio x1 in the multiple stacked bodies SL. The fluctuation dy1 of the Al composition ratio y1 of the second layer 42 between the multiple stacked bodies SL is within plus or minus 15% of the average ay1 of the Al composition ratio y1 in the multiple stacked bodies SL. The fluctuation dy2 of the Al composition ratio y2 of the third layer 43 between the multiple stacked bodies SL is within plus or minus 15% of the average ay2 of the Al composition ratio y2 in the multiple stacked bodies SL.

In the semiconductor light emitting element and the method for manufacturing the semiconductor light emitting element according to the embodiments, the method for depositing the semiconductor layer may include, for example, metal-organic chemical vapor deposition (MOCVD), metal-organic vapor phase epitaxy (MOVPE), molecular beam epitaxy (MBE), hydride vapor phase epitaxy (HVPE), etc.

For example, in the case where MOCVD or MOVPE is used, the following source materials may be used when forming the semiconductor layers. For example, TMGa (trimethylgallium) and TEGa (triethylgallium) may be used as the source material of Ga. For example, TMIn (trimethylindium), TEIn (triethylindium), etc., may be used as the source material of In. For example, TMAI (trimethyl aluminum), etc., may be used as the source material of Al. For example, NH₃ (ammonia), MMHy (monomethylhydrazine), DMHy (dimethylhydrazine), etc., may be used as the source material of N. SiH₄ (monosilane), Si₂H₆ (disilane), etc., may be used as the source material of Si.

According to the embodiments, a semiconductor light emitting element and a method for manufacturing the semiconductor light emitting element having high luminous efficiency can be provided.

In the specification, “nitride semiconductor” includes all compositions of semiconductors of the chemical formula BₓIn_{y}Al_{z}Ga_{1-x-y-z}N (0≦x≦1, 0≦y≦1, 0≦z≦1, and x+y+z≦1) for which the composition ratios x, y, and z are changed within the ranges respectively. “Nitride semiconductor” further includes group V elements other than N (nitrogen) in the chemical formula recited above, various elements added to control various properties such as the conductivity type and the like, and various elements included unintentionally.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, embodiments of the invention are described with reference to specific examples. However, the invention is not limited to these specific examples. For example, one skilled in the art may similarly practice the invention by appropriately selecting specific configurations of components included in the semiconductor light emitting element such as the semiconductor layer, the light emitting layer, the intermediate unit, the buffer layer, the substrate, etc., from known art; and such practice is within the scope of the invention to the extent that similar effects can be obtained.

Further, any two or more components of the specific examples may be combined within the extent of technical feasibility and are included in the scope of the invention to the extent that the purport of the invention is included.

Moreover, all semiconductor light emitting elements and methods for manufacturing the same practicable by an appropriate design modification by one skilled in the art based on the semiconductor light emitting elements and the methods for manufacturing the same described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor light emitting element, comprising:
a first semiconductor layer of a first conductivity type;
a second semiconductor layer of a second conductivity type separated from the first semiconductor layer in a first direction;
a light emitting layer provided between the first semiconductor layer and the second semiconductor layer, the light emitting layer including a well layer including a nitride semiconductor including In; and
a first intermediate unit provided between the first semiconductor layer and the light emitting layer,
the first intermediate unit including a plurality of stacked bodies,
the stacked bodies being arranged in the first direction,
each of the stacked bodies including:
a first layer of Inₓ₁Ga₁₋ₓ₁N (0<x1<1);
a second layer of Al_{y1}Ga_{1-y1}N (0<y1<1) provided between the first layer and the light emitting layer, to contact the first layer; and
a third layer of Al_{y2}Ga_{1-y2}N (0≦y2<y1) provided between the second layer and the light emitting layer, to contact the second layer,
a screw dislocation density of the first semiconductor layer being 1×10⁸/cm² or more.

2. The element according to claim 1, wherein the screw dislocation density is not less than 0.2 times and not more than 0.4 times an edge dislocation density of the first semiconductor layer.

3. The element according to claim 1, wherein the screw dislocation density is a value obtained from a rocking curve width at half maximum of X-ray diffraction of the first semiconductor layer.

4. The element according to claim 3, wherein the edge dislocation density is obtained from the rocking curve width at half maximum of the X-ray diffraction of the first semiconductor layer and is not more than 6.0×10⁸/cm².

5. A semiconductor light emitting element, comprising:
a first semiconductor layer of a first conductivity type formed on a silicon substrate;
a first intermediate unit provided on the first semiconductor layer;
a light emitting layer provided on the first intermediate unit, the light emitting layer including a well layer including a nitride semiconductor including In; and
a second semiconductor layer of a second conductivity type provided on the light emitting layer,
the first intermediate unit including a plurality of stacked bodies,
the stacked bodies being arranged in a first direction from the first semiconductor layer toward the second semiconductor layer,
each of the stacked bodies including:
a first layer of Inₓ₁Ga₁₋ₓ₁N (0<x1<1);
a second layer of Al_{y1}Ga_{1-y1}N (0<y1<1) provided between the first layer and the light emitting layer to contact the first layer; and
a third layer of Al_{y2}Ga_{1-y2}N (0≦y2<y1) provided between the second layer and the light emitting layer to contact the second layer.

6. The element according to claim 1, wherein
a thickness of the second layer is not more than a thickness of the first layer, and
the thickness of the second layer is thinner than a thickness of the third layer.

7. The element according to claim 6, wherein
fluctuation of the thickness of the first layer between the stacked bodies is within plus or minus 15% of an average of the thickness of the first layer in the stacked bodies,
fluctuation of the thickness of the second layer between the stacked bodies is within plus or minus 15% of an average of the thickness of the second layer in the stacked bodies, and
fluctuation of the thickness of the third layer between the stacked bodies is within plus or minus 15% of an average of the thickness of the third layer in the stacked bodies.

8. The element according to claim 6, wherein
the thickness of the first layer is not less than 0.9 nanometers and not more than 1.1 nanometers;
the thickness of the second layer is not less than 0.9 nanometers and not more than 1.1 nanometers, and
the thickness of the third layer is not less than 1.8 nanometers and not more than 2.2 nanometers.

9. The element according to claim 1, wherein fluctuation of the In composition ratio x1 of the first layer between the stacked bodies is within plus or minus 15% of an average of the x1 in the stacked bodies.

10. The element according to claim 1, wherein fluctuation of the Al composition ratio y1 of the second layer between the stacked bodies is within plus or minus 15% of an average of the y1 in the stacked bodies.

11. The element according to claim 1, wherein a number of the stacked bodies is 16 or more.

12. The element according to claim 1, wherein
the well layer includes In_{w1}Ga_{1-w1}N (0<w1<1), and
the light emitting layer further includes:
a first barrier region of Al_{b1}Ga_{1-b1}N (0<b1≦1) provided between the well layer and the second semiconductor layer to contact the well layer; and
a second barrier region of Al_{b2}Ga_{1-b2}N (0≦b2<b1) provided between the first barrier region and the second semiconductor layer to contact the first barrier region.

13. The element according to claim 1, further comprising a second intermediate unit,
the first semiconductor layer being disposed between the second intermediate unit and the first intermediate unit,
the second intermediate unit including a nitride including one of silicon, magnesium, or boron.

14. The element according to claim 13, wherein a thickness of the second intermediate unit is 3 nanometers or less.

15. A method for manufacturing a semiconductor light emitting element, comprising:
forming a first semiconductor layer of a first conductivity type on a silicon substrate;
forming a first intermediate unit on the first semiconductor layer;
forming a light emitting layer on the first intermediate unit, the light emitting layer including a well layer including a nitride semiconductor including In; and
forming a second semiconductor layer of a second conductivity type on the light emitting layer,
the forming of the first intermediate unit including forming a plurality of stacked bodies,
the stacked bodies being arranged in a direction intersecting the silicon substrate,
each of the stacked bodies including:
a first layer of Inₓ₁Ga₁₋ₓ₁N (0<x1<1);
a second layer of Al_{y1}Ga_{1-y1}N (0<y1<1) provided on the first layer to contact the first layer; and
a third layer of Al_{y2}Ga_{1-y2}N (0≦y2<y1) provided on the second layer to contact the second layer.

16. The method according to claim 15, wherein
a thickness of the second layer is not more than a thickness of the first layer, and
the thickness of the second layer is thinner than a thickness of the third layer.

17. The method according to claim 16, wherein
fluctuation of the thickness of the first layer between the stacked bodies is within plus or minus 15% of an average of the thickness of the first layer in the stacked bodies,
fluctuation of the thickness of the second layer between the stacked bodies is within plus or minus 15% of an average of the thickness of the second layer in the stacked bodies, and
fluctuation of the thickness of the third layer between the stacked bodies is within plus or minus 15% of an average of the thickness of the third layer in the stacked bodies.

18. The method according to claim 16, wherein
the thickness of the first layer is not less than 0.9 nanometers and not more than 1.1 nanometers,
the thickness of the second layer is not less than 0.9 nanometers and not more than 1.1 nanometers, and
the thickness of the third layer is not less than 1.8 nanometers and not more than 2.2 nanometers.

19. The element according to claim 15, wherein fluctuation of the In composition ratio x1 of the first layer between the stacked bodies is within plus or minus 15% of an average of the x1 in the stacked bodies.

20. The method according to claim 15, wherein fluctuation of the Al composition ratio y1 of the second layer between the stacked bodies is within plus or minus 15% of an average of the y1 in the stacked bodies.
